(19) United States
(12) Patent Application Publication
(10) Pub. No.: US 2009/0110017 A1
(43) Pub. Date: Apr. 30, 2009

(54) SEMICONDUCTOR LIGHT-EMITTING ELEMENT AND METHOD OF MANUFACTURING THE SAME

(75) Inventor: Masami Aihara, Miyagi-ken (JP)

Correspondence Address: BRINKS HOFER GILSON & LIONE, P.O. BOX 10395, CHICAGO, IL, 60610, US

(73) Assignee: Alps Electric Co., Ltd., Tokyo (JP)

(21) Appl. No.: 12/275,750

(22) Filed: Nov. 21, 2008

(30) Foreign Application Priority Data
May 23, 2006 (JP) JP 2006-142926
May 22, 2007 (JP) PCT/JP2007/060449

(51) Int. Cl. H01S 5/00; H01L 21/02

(52) U.S. Cl. 372/44.01; 438/46; 257/E21.002

(57) ABSTRACT

A semiconductor light-emitting element includes a semiconductor layer including a light-emitting layer, a refractive index gradient layer provided on a light extraction surface of the semiconductor layer, and a holding substrate bounded to an outer surface of the refractive index gradient layer with an adhesion layer interposed therebetween. A refractive index of the refractive index gradient layer is changed continuously or stepwise in a film thickness direction such that a semiconductor-layer-side refractive index is substantially equivalent to a refractive index of the semiconductor layer and a holding-substrate-side refractive index is substantially equivalent to a refractive index of the holding substrate. The refractive index gradient layer is formed by vapor plating.

### RELATED APPLICATIONS

This application claims benefit of the Japanese Patent Application No. 2006-142926 filed on May 23, 2006, which is hereby incorporated by reference.

### BACKGROUND

1. Field of the Invention

The present invention relates to a semiconductor light-emitting element and a method of manufacturing the semiconductor light-emitting element, and more particularly to a flip chip semiconductor light-emitting element having a semiconductor layer with high crystal quality and providing high light extraction efficiency, and a method of easily and inexpensively manufacturing such a semiconductor light-emitting element.

2. Description of the Related Art

Hitherto, a flip chip semiconductor light-emitting element has been known, the semiconductor light-emitting element having a sapphire substrate and a GaN-based semiconductor layer provided on the sapphire substrate. In such a semiconductor light-emitting element, the sapphire substrate has a refractive index of about 1.8, and the GaN-based semiconductor layer has a refractive index of about 2.5. Hence, a waveguide is formed inside the GaN-based semiconductor layer, resulting in a problem that light emitted from the GaN-based semiconductor layer is not efficiently output to the outside.

As means for solving the problem, a technique for forming a refractive index transition region on a semiconductor-layer formation surface of the sapphire substrate by implanting at least one type of ion into the sapphire substrate by ion implantation method, and after the ion implantation, treating the sapphire substrate with heat. In the refractive index transition region, a refractive index is changed from a value equivalent to or approximated to the refractive index of the sapphire substrate, to a value equivalent to or approximated to the refractive index of the GaN-based semiconductor layer in a film thickness direction (for example, see Japanese Unexamined Patent Application Publication No. 2005-109284).

With the technique, the refractive index of the refractive index transition region can be equivalent to or approximated to the refractive index of the sapphire substrate at an interface therebetween. Also, the refractive index of the refractive index transition region can be equivalent to or approximated to the refractive index of the GaN-based semiconductor layer at an interface therebetween. Accordingly, a reflection component of light can be reduced, and light extraction efficiency can be enhanced.

However, in the technique described in Patent Document 1, the refractive index transition region is formed into the sapphire substrate by the ion implantation, resulting in a manufacturing facility becoming large, a manufacturing work taking a long time, and a semiconductor light-emitting element as a product becoming expensive. Also, the ion implantation roughens the surface of the sapphire substrate, resulting in crystal quality of the GaN-based semiconductor layer to be formed on the surface being deteriorated, and internal quantum efficiency originally owned by the semiconductor layer being reduced. It is to be noted that the sapphire substrate has a high melting point, and hence, it is difficult to reduce the surface roughness of the sapphire substrate due to the ion implantation and heat treatment.

### BRIEF SUMMARY

In light of the above situations, the present invention provides a flip chip semiconductor light-emitting element having a semiconductor layer with high crystal quality and providing high light extraction efficiency, and a method of easily and inexpensively manufacturing the semiconductor light-emitting element.

To overcome the above-described problems, the present invention provides a first configuration for a semiconductor light-emitting element including a semiconductor layer including a light-emitting layer; a refractive index gradient layer provided on a light extraction surface of the semiconductor layer; and a holding substrate bonded to an outer surface of the refractive index gradient layer with an adhesion layer interposed therebetween. The holding substrate and the adhesion layer are transparent to light emitted from the semiconductor layer. A refractive index of the holding substrate is substantially equivalent to a refractive index of the adhesion layer and smaller than a refractive index of the semiconductor layer. A refractive index of the refractive index gradient layer is changed continuously or stepwise in a film thickness direction such that a semiconductor-layer-side refractive index is substantially equivalent to the refractive index of the semiconductor layer and a holding-substrate-side refractive index is substantially equivalent to the refractive index of the holding substrate.

As described above, the semiconductor light-emitting element includes the semiconductor layer, the refractive index gradient layer provided on the light extraction surface of the semiconductor layer, and the holding substrate bonded to the outer surface of the refractive index gradient layer with the adhesion layer interposed therebetween. Hence, the refractive index gradient layer may be formed on the surface of the semiconductor layer before the holding substrate is bonded. Accordingly, the refractive index gradient layer can be formed by using a technique of vapor plating such as plasma CVD instead of ion implantation to a sapphire substrate. Thus, a semiconductor light-emitting element having high light extraction efficiency can be inexpensively manufactured. In addition, since ion does not have to be implanted into the sapphire substrate, crystal quality of the semiconductor layer is not deteriorated, and reduction in internal quantum efficiency originally owned by the semiconductor layer can be prevented.

Also, in view of the semiconductor light-emitting element according to the first configuration, the present invention may provide a second configuration. In the second configuration, the semiconductor layer may be made of a GaN-based semiconductor layer, the holding substrate may be made of SiO₂, the adhesive layer may be made of epoxy resin, and the refractive index gradient layer may be made of an inorganic dielectric layer having a composition being changed in the film thickness direction.

A refractive index of an inorganic dielectric, such as SiO or SiN, may be adjusted by adjusting a composition thereof during film formation. That is, the refractive index gradient layer having the semiconductor-side refractive index substantially equivalent to the refractive index of the semiconductor layer and having the holding-substrate-side refractive index substantially equivalent to the refractive index of the holding substrate can be relatively easily manufactured.

Also, in view of the semiconductor light-emitting element according to the second configuration, the present invention may provide a configuration. In the configuration, the semiconductor-layer-side refractive index of the refractive index gradient layer may be in a range of from 2.0 to 2.9, and the holding-substrate-side refractive index of the refractive index gradient layer may be in a range of from 1.4 to 1.6.

A refractive index of the GaN-based semiconductor layer is in a range of from 2.0 to 2.9 around a value of about 2.5, and refractive indices of SiO₂ and epoxy resin are in a range of from 1.4 to 1.6 around a value of about 1.5. In contrast, the refractive index of the inorganic dielectric, such as SiO or SiN, can be changed within a range of from 1.4 to 2.9 by adjusting the composition thereof during film formation. Accordingly, a semiconductor light-emitting element having high light extraction efficiency can be provided. By adjusting the refractive index of the refractive index gradient layer as described above, the refractive indices at an interface between the GaN-based semiconductor layer and the refractive index gradient layer can be equivalent or approximated to each other, and the refractive indices at an interface between the refractive index gradient layer and the holding substrate (adhesion layer) can be equivalent or approximated to each other. Accordingly, a semiconductor light-emitting element having high light extraction efficiency can be provided.

Meanwhile, the present invention provides a first configuration for a method of manufacturing a semiconductor light-emitting element, the first configuration including the steps of forming a semiconductor layer on a surface of a sapphire substrate; mounting a support substrate on the semiconductor layer, the support substrate temporarily supporting the semiconductor layer; separating the sapphire substrate from the semiconductor layer at an interface between the sapphire substrate and the semiconductor layer, thereby exposing the semiconductor layer; forming a refractive index gradient layer on a surface of the exposed semiconductor layer by vapor plating, the refractive index gradient layer having a refractive index being changed in a film thickness direction; bonding a holding substrate to a surface of the refractive index gradient layer with an adhesion layer interposed therebetween, the holding substrate being transparent to light emitted from the semiconductor layer; and separating the support substrate from the semiconductor layer at an interface between the semiconductor layer and the support substrate.

With the method, the refractive index gradient layer having the refractive index being changed in the film thickness direction is formed by vapor plating on the surface of the semiconductor layer exposed by separating the sapphire substrate. Accordingly, a semiconductor light-emitting element having higher light extraction efficiency as compared with the case using the ion implantation can be easily and inexpensively manufactured.

Also, in view of the method of manufacturing the semiconductor light-emitting element according to the first configuration, the present invention may provide a second configuration for the method of manufacturing the semiconductor light-emitting element. In the second configuration, when the refractive index gradient layer is formed, the semiconductor layer supported by the support substrate may be placed in a plating chamber of a plasma CVD device, and a composition of source gas to be supplied into the plating chamber may be properly changed in accordance with a film thickness of the refractive index gradient layer formed on the semiconductor layer.

Since the refractive index gradient layer may be formed on the semiconductor layer by using the plasma CVD device, an inorganic dielectric layer having a refractive index being changed in a film thickness direction can be easily formed by properly changing the composition of the source gas to be supplied into the plating chamber. A refractive index gradient layer, and a desired semiconductor light-emitting element can be manufactured highly efficiently.

### BRIEF DESCRIPTION OF THE DRAWINGS

FIG. 1 is a cross-sectional view showing a semiconductor light-emitting element according to an embodiment of the present invention;

FIG. 2 is a table showing effects of semiconductor light-emitting elements according to an example of the present invention as compared with semiconductor light-emitting elements without a refractive index gradient layer;

FIG. 3 is a flowchart showing a manufacturing procedure of the semiconductor light-emitting element according to an embodiment of the present invention; and

FIG. 4 is a table showing a change in flow rate of source gas when the refractive index gradient layer is formed.

### DETAILED DESCRIPTION OF THE DRAWINGS AND THE PRESENTLY PREFERRED EMBODIMENTS

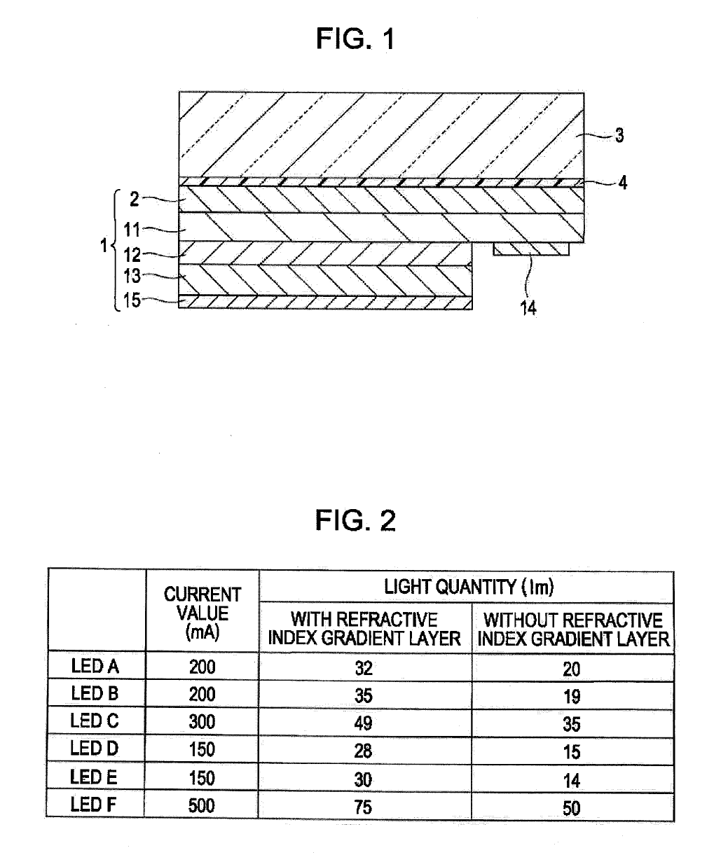

An exemplary semiconductor light-emitting element according to an embodiment of the present invention is described below with reference to FIGS. 1 and 2. FIG. 1 is a cross-sectional view showing a semiconductor light-emitting element according to the embodiment of the present invention. FIG. 2 is a table showing effects of semiconductor light-emitting elements according to an example of the present invention as compared with semiconductor light-emitting elements without a refractive index gradient layer.

Referring to FIG. 1, the semiconductor light-emitting element of this embodiment includes a semiconductor layer 1, a refractive index gradient layer 2 provided on a light extraction surface of the semiconductor layer 1, a holding substrate 3 provided on an outer surface (light extraction side) of the refractive index gradient layer 2, and an adhesion layer 4 for bonding the refractive index gradient layer 2 and the holding substrate 3.

Referring to FIG. 1, the semiconductor layer 1 includes an n-GaN layer 11, a light-emitting layer 12, a p-GaN layer 13, an n-electrode 14 provided on the n-GaN layer 11, and a p-electrode 15 provided on the p-GaN layer 13. The layer structure of the layers of the semiconductor layer 1 is not limited to the structure shown in FIG. 1, and a semiconductor having any known layer structure may be provided. Also, the layer technique of the semiconductor layer 1 is not a primary part of the present invention and is known. Thus, the layer technique is not described in the specification.

The holding substrate 3 protects the semiconductor layer 1. The holding substrate 3 may be made of a material, such as glass (SiO₂) or plastic, being transparent to the light emitted from the semiconductor layer 1 and having a proper hardness. The refractive index of the holding substrate 3 made of glass or plastic is about 1.5.

The adhesion layer 4 bonds the refractive index gradient layer 2 and the holding substrate 3. The adhesion layer 4 is made of a resin material transparent to light emitted from the semiconductor layer 1. Any known resin material may be used as long as the material is transparent. In particular, epoxy resin may be preferably used because epoxy resin has high adhesive force and the refractive index of the epoxy resin is about 1.5, the refractive index being approximated to the refractive index of the holding substrate 3.

The refractive index gradient layer 2 may be made of an inorganic dielectric, such as SiO or SiN, with a thickness ranging from about 200 to about 300 nm. A refractive index of the refractive index gradient layer 2 is changed continuously or stepwise within a film thickness in a film thickness direction such that a semiconductor-layer-1-side refractive index is substantially equivalent to a refractive index of the semiconductor layer 1 and a holding-substrate-3-side refractive index is substantially equivalent to a refractive index of the holding substrate 3. For example, the semiconductor layer 1 may be made of a GaN-based semiconductor layer, the holding substrate 3 may be made of SiO₂, and the adhesion layer 4 may be made of epoxy resin. In this case, the average refractive index of the GaN-based semiconductor layer is about 2.5, and the refractive indices of SiO₂ and epoxy resin are about 1.5. Hence, the refractive index of the refractive index gradient layer 2 is adjusted so as to be gradually changed within this range in one direction in the film thickness direction such that the semiconductor-layer-1-side refractive index is about 2.5, the holding-substrate-3-side (adhesion-layer-4-side) refractive index is about 1.5. The refractive index is adjusted preferably by changing the composition of the inorganic dielectric serving as a material in the film thickness direction during film formation.

The semiconductor light-emitting element of this embodiment includes the semiconductor layer 1 including the light-emitting layer 12, the refractive index gradient layer 2 provided on the light extraction surface of the semiconductor layer 1, and the holding substrate 3 bonded to the outer surface of the refractive index gradient layer 2 with the adhesion layer 4 interposed therebetween. Accordingly, the semiconductor light-emitting element has high light extraction efficiency. Also, the refractive index gradient layer 2 is formed between the semiconductor layer 1 and the holding substrate 3 by plasma CVD method. Accordingly, the semiconductor light-emitting element can be manufactured inexpensively, the crystal quality of the semiconductor layer 1 is not deteriorated, and resultant reduction in internal quantum efficiency originally owned by the semiconductor layer can be prevented.

A sample with the refractive index gradient layer 2 and a sample without the refractive index gradient layer 2 were fabricated for each of semiconductor light-emitting elements (LEDs) A and B with a rated current value of 200 mA and an emission wavelength of 460 nm, a semiconductor light-emitting element C with a rated current value of 300 mA and an emission wavelength of 460 nm, semiconductor light-emitting elements D and E with a rated current value of 150 mA and an emission wavelength of 460 nm, and a semiconductor light-emitting element F with a rated current value of 500 mA and an emission wavelength of 460 nm. The light quantity of light output from each of the semiconductor light-emitting elements was measured. As a result, referring to FIG. 2, the light quantities of the semiconductor light-emitting elements A and B with the rated current value of 200 mA increased by a rate ranging from 60% to 84%, the light quantity of the semiconductor light-emitting element C with the rated current value of 300 mA increased by 40%, the light quantities of the semiconductor light-emitting elements D and E with the rated current value of 150 mA increased by a rate ranging from 87% to 114%, and the light quantity of the semiconductor light-emitting element F with the rated current value of 500 mA increased by 50%. Thus, it was found that the semiconductor light-emitting elements according to the example of the present invention be markedly effective for enhancement of the light extraction efficiency.

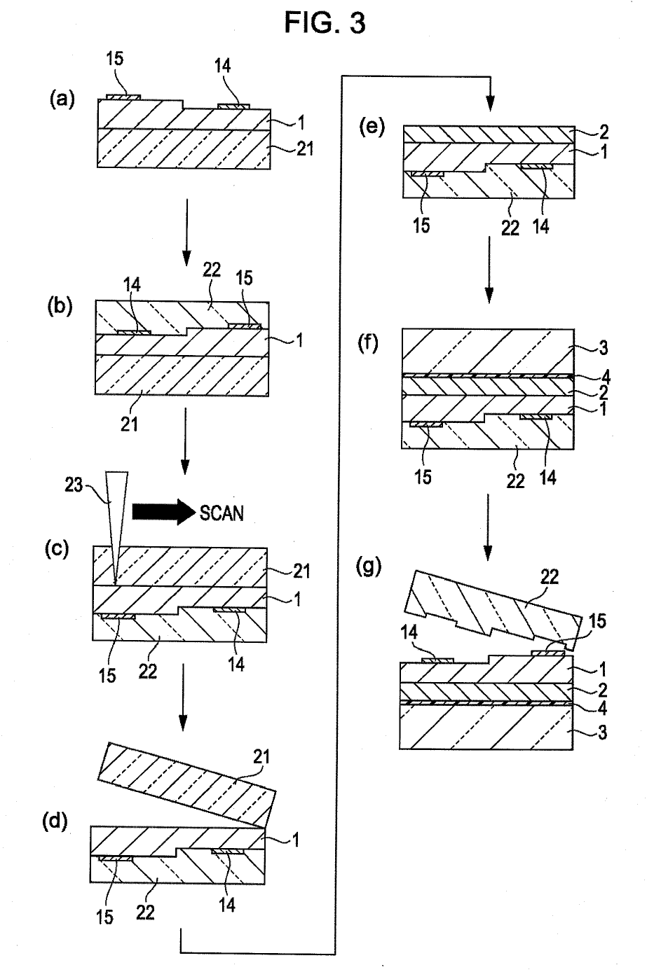

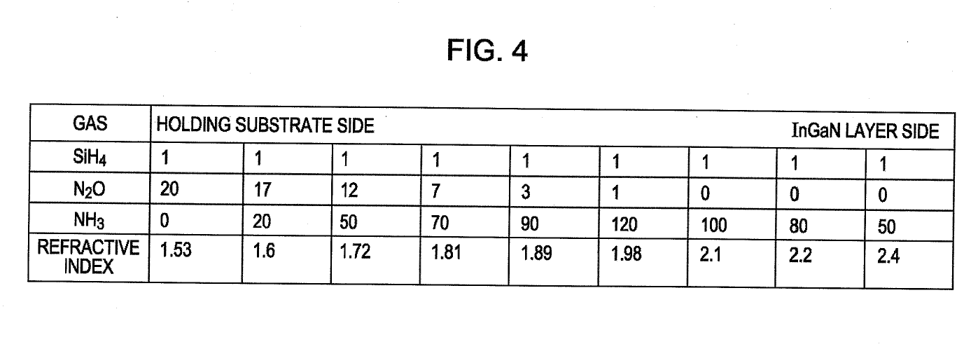

Now, an exemplary method of manufacturing the semiconductor light-emitting element according to an embodiment of the present invention is described with reference to FIGS. 3 and 4. FIG. 3 is a flowchart showing a manufacturing procedure of the semiconductor light-emitting element according to the embodiment of the present invention. FIG. 4 is a table showing a change in flow rate of source gas when the refractive index gradient layer is formed.

First, referring to FIG. 3(a), the semiconductor layer 1 including the light-emitting layer 12, n-electrode 14, and p-electrode 15, though not illustrated, is formed on a surface of a sapphire substrate 21 by a known method. Next, referring to FIG. 3(b), a support substrate 22 made of, for example, a glass plate, supports an electrode formation surface of the semiconductor layer 1. Then, referring to FIG. 3(c), an excimer laser 23 with a wavelength of 308 or 248 nm is focused on an interface between the semiconductor layer 1 and the sapphire substrate 21. While the condition is maintained, the excimer laser 23 scans the semiconductor layer 1 in a plane direction. Accordingly, an interface portion between the semiconductor layer 1 and the sapphire substrate 21 is melted, and referring to FIG. 3(d), the sapphire substrate 21 is separated from the semiconductor layer 1. Then, the semiconductor layer 1 supported by the support substrate 22 may be preferably placed in a plating chamber of a plasma CVD device. Referring to FIG. 3(e), the refractive index gradient layer 2 is formed on the light extraction surface of the semiconductor layer 1. When the refractive index gradient layer 2 is formed, the flow rate of source gas (SiH₄, N₂O, NH₃) to be supplied into the plating chamber may be changed as shown in FIG. 4 as the film thickness of the refractive index gradient layer 2 increases from the semiconductor layer 1 side. Next, referring to FIG. 3(f), the holding substrate 3 is bonded to the surface of the formed refractive index gradient layer 2 with the adhesion layer 4 interposed therebetween. Finally, referring to FIG. 3(g), the support substrate 22 is separated, and a semiconductor light-emitting element is obtained as a product.

With the method of manufacturing the semiconductor light-emitting element according to this embodiment, while the semiconductor layer 1 is temporarily supported by the support substrate 22, the sapphire substrate 21 is separated from the semiconductor layer 1 formed on the sapphire substrate 21, at the interface between the sapphire substrate 21 and the semiconductor layer 1, and the refractive index gradient layer 2 having the refractive index being changed in the film thickness direction is formed on the surface of the exposed semiconductor layer 1 by plasma CVD. Accordingly, a semiconductor light-emitting element having higher light extraction efficiency as compared with the case using the ion implantation can be easily and inexpensively manufactured.

1. A semiconductor light-emitting element comprising:
a semiconductor layer including a light-emitting layer;
a refractive index gradient layer provided on a light extraction surface of the semiconductor layer; and
a holding substrate bonded to an outer surface of the refractive index gradient layer with an adhesion layer interposed therebetween,
wherein the holding substrate and the adhesion layer are transparent to light emitted from the semiconductor layer,
wherein a refractive index of the holding substrate is substantially equivalent to a refractive index of the adhesion layer and smaller than a refractive index of the semiconductor layer, and
wherein a refractive index of the refractive index gradient layer is changed continuously or stepwise in a film thickness direction such that a semiconductor-layer-side refractive index is substantially equivalent to the refractive index of the semiconductor layer and a holding-substrate-side refractive index is substantially equivalent to the refractive index of the holding substrate.

2. The semiconductor light-emitting element according to claim 1, wherein the semiconductor layer is made of a GaN-based semiconductor layer, the holding substrate is made of SiO₂, the adhesive layer is made of epoxy resin, and the refractive index gradient layer is made of an inorganic dielectric layer having a composition being changed in the film thickness direction.

3. The semiconductor light-emitting element according to claim 2, wherein the semiconductor-layer-side refractive index of the refractive index gradient layer is in a range of from 2.0 to 2.9, and the refractive index of the holding-substrate-side refractive index gradient layer is in a range of from 1.4 to 1.6.

4. A method of manufacturing a semiconductor light-emitting element, the method comprising the steps of:
forming a semiconductor layer on a surface of a sapphire substrate;
mounting a support substrate on the semiconductor layer, the support substrate temporarily supporting the semiconductor layer;
separating the sapphire substrate from the semiconductor layer at an interface between the sapphire substrate and the semiconductor layer, thereby exposing the semiconductor layer;
forming a refractive index gradient layer on a surface of the exposed semiconductor layer by vapor plating, the refractive index gradient layer having a refractive index being changed in a film thickness direction;
bonding a holding substrate to a surface of the refractive index gradient layer with an adhesion layer interposed therebetween, the holding substrate being transparent to light emitted from the semiconductor layer; and
separating the support substrate from the semiconductor layer at an interface between the semiconductor layer and the support substrate.

5. The method of manufacturing the semiconductor light-emitting element according to claim 4, wherein when the refractive index gradient layer is formed, the semiconductor layer supported by the support substrate is placed in a plating chamber of a plasma cvd device, and a composition of source gas to be supplied into the plating chamber is properly changed in accordance with a film thickness of the refractive index gradient layer formed on the semiconductor layer.
